(19) United States
(12) Patent Application Publication
(10) Pub. No.: US 2003/0232471 A1
(43) Pub. Date: Dec. 18, 2003

(54) Semiconductor device and method of fabricating the same

(75) Inventor: Yuichi Yokoyama, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/326,143

(22) Filed: Dec. 23, 2002

(30) Foreign Application Priority Data
Jun. 17, 2002 (JP) 2002-175717(P)

(51) Int. Cl. H01L 21/8242; H01L 23/48; H01L 23/52; H01L 29/40; H01L 21/4763

(52) U.S. Cl. 438/253; 438/254; 438/255; 438/256; 438/638; 438/640; 257/774; 257/775

(57) ABSTRACT

A method of fabricating a semiconductor device includes steps of forming an interlayer dielectric film to cover upper sides of a bit line pad and a storage node pad defining a first conductive layer, simultaneously forming a plurality of contact holes reaching upper surface of the first conductive layer through the interlayer dielectric film, expanding in width upper portion of part of the aforementioned plurality of contact holes, thereby forming a trench for a second conductive layer, and arranging conductors in the aforementioned plurality of contact holes and the aforementioned trench for a second conductive layer. Thus, a bit line contact, a storage node contact and a bit line serving as the second conductive layer are obtained.

### BACKGROUND OF THE INVENTION

1. Field of the Invention

The present invention relates to a semiconductor device, and more particularly, it relates to a DRAM (dynamic random-access memory) comprising a storage node.

2. Description of the Background Art

A conventional method of fabricating a semiconductor device is now described with reference to FIGS. 11 to 20.

First, the structure shown in FIG. 11 is fabricated by a well-known technique. In the structure shown in FIG. 11, transfer gate electrodes 2 are formed on the main surface of a silicon substrate 1, and the upper sides thereof are covered with an interlayer dielectric film 5. Bit line contacts and a storage node contact are provided to vertically pass through the interlayer dielectric film 5, and the upper portions thereof are exposed flush with the upper surface of the interlayer dielectric film 5, thereby forming bit line pads 3 and a storage node pad 4 respectively.

As shown in FIG. 12, an interlayer dielectric film 9 is formed to cover the upper side of the structure shown in FIG. 11. As shown in FIG. 13, a resist film 31 is formed to cover the upper side of the interlayer dielectric film 9 and patterned to have openings only in portions located immediately above the bit line pads 3, for etching the interlayer dielectric film 9 through the resist film 31 serving as a mask. Thus, not the upper surface of the storage node pad 4 but only the upper surfaces of the bit line pads 3 are exposed on the bottoms of the vertical openings, as shown in FIG. 13. As shown in FIG. 14, the resist film 31 is removed and a conductor film 12 is formed to cover the upper surface of the structure. This conductive film 12 is formed to fill up the vertical openings. An insulator film 13 is formed to cover the upper surface of the conductor film 12, and a resist film 32 is formed to cover the upper surface thereof. The resist film 32 is patterned along a pattern for arranging bit lines 14 and employed as a mask for etching the insulator film 13, as shown in FIG. 15. The insulator film 13 partially remains according to the pattern for arranging the bit lines 14. The resist film 32 is removed and the conductor film 12 is etched through the remaining parts of the insulator film 13 serving as masks, thereby obtaining a structure shown in FIG. 16. Thus, bit line contacts 6 and the bit lines 14 are obtained from the conductor film 12 shown in FIG. 15.

As shown in FIG. 17, the upper side of the structure is covered with an interlayer dielectric film 11. A resist film 33 is formed to cover the upper side of the interlayer dielectric film 11. This resist film 33 is patterned to have an opening only in a portion located immediately above the storage node pad 4. The resist film 33 is employed as a mask for performing etching through the interlayer dielectric films 11 and 9. Consequently, the storage node pad 4 is exposed on the bottom of the vertical opening as shown in FIG. 18. As shown in FIG. 19, this vertical opening is filled up with a conductor thereby forming a storage node contact 7, and the upper sides of the storage node contact 7 and the interlayer dielectric film 11 are covered with an interlayer dielectric film 15. A resist film 34 is formed to cover the upper surface of the interlayer dielectric film 15. The resist film 34 is patterned to have an opening only in a portion located immediately above the storage node contact 7. The resist film 34 is employed as a mask for performing etching, thereby forming a vertical opening. As shown in FIG. 20, a storage node electrode 16 is formed in the shape of a cylinder covering the inner surface of the vertical opening, an insulator film (not shown) is formed to cover the storage node electrode 16, and a cell plate electrode 17 is formed to cover the surface of the insulator film formed in the vertical opening and the upper surface of the interlayer dielectric film 15. Thus, a semiconductor device comprising a cylindrical storage node 18 is obtained.

In the aforementioned conventional method, however, four resist films 31, 32, 33 and 34 must be used for completing the storage node 18 as shown in FIG. 20 from the state exposing the bit line pads 3 and the storage node pad 4 on the upper surface of the interlayer dielectric film 5 as shown in FIG. 11. The number of resist films employed for fabricating a semiconductor device is directly related to the number of steps and the quantity of a resist material employed for the films. Thus, the number of the resist films is desirably reduced to the minimum.

In the conventional structure, further, the total thickness of the interlayer dielectric films 11 and 9 for receiving the storage node contact 7 therein is about 600 nm and the aspect ratio of the vertical opening to be formed at a time is so large that the frontage diameter of such a deep vertical opening is disadvantageously enlarged by about 20 nm when the same is formed by single etching. In this case, the vertical opening is formed by anisotropic dry etching.

### SUMMARY OF THE INVENTION

An object of the present invention is to provide a semiconductor device and a method of fabricating the same, capable of reducing the number of employed resist films as well as the aspect ratio of a vertical opening to be formed by single etching in a fabrication step.

In order to attain the aforementioned object, the method of fabricating a semiconductor device according to the present invention includes steps of forming an interlayer dielectric film to cover the upper side of a first conductive layer, simultaneously forming a plurality of contact holes reaching the upper surface of the aforementioned first conductive layer through the aforementioned interlayer dielectric film, expanding in width the upper portion of part of the aforementioned plurality of contact holes, thereby forming a trench for a second conductive layer, and arranging conductors in the aforementioned plurality of contact holes and the aforementioned trench for a second conductive layer.

In order to attain the aforementioned object, further, the semiconductor device according to the present invention comprises an interlayer dielectric film covering the upper side of a first conductive layer, a plurality of contact holes having conductors arranged therein and a second conductive layer larger in width than the aforementioned plurality of contact holes. The second conductive layer is connected to the upper side of part of the aforementioned plurality of contact holes. The upper surface of the aforementioned second conductive layer and the upper surfaces of those of the aforementioned plurality of contact holes not formed with the aforementioned second conductive layer are substantially flush with each other.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 8 are explanatory diagrams of first to eighth steps in a method of fabricating a semiconductor device according to a first embodiment of the present invention;

FIG. 9 is an explanatory diagram of a ninth step in the method of fabricating a semiconductor device according to the first embodiment of the present invention as well as a sectional view of a semiconductor device according to a second embodiment of the present invention;

FIG. 10 is a sectional view of a semiconductor device according to a third embodiment of the present invention; and

FIGS. 11 to 20 are first to tenth explanatory diagrams showing a conventional method of fabricating a semiconductor device.

### DESCRIPTION OF THE PREFERRED EMBODIMENTS

(First Embodiment)

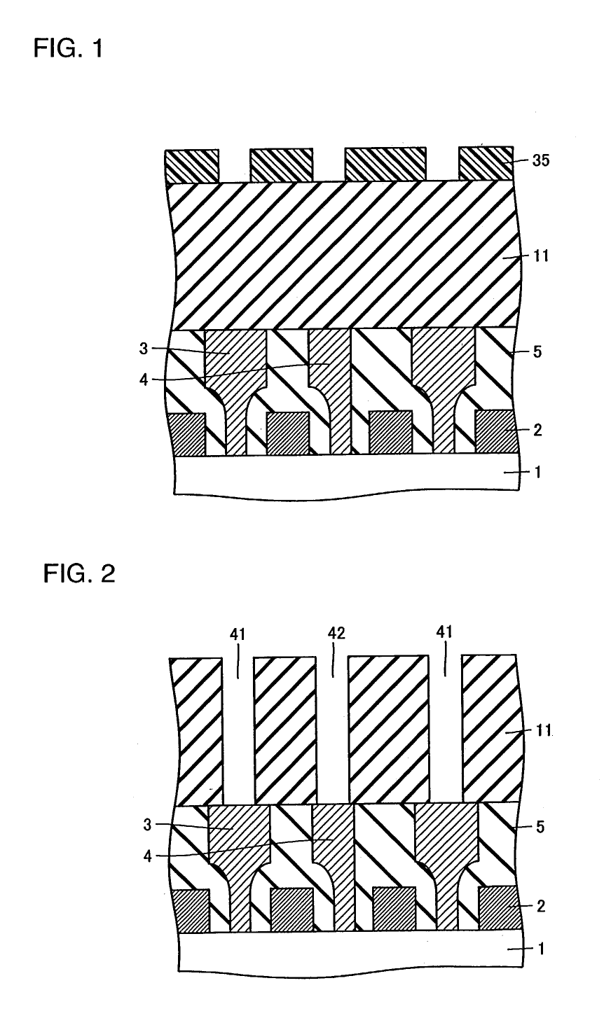

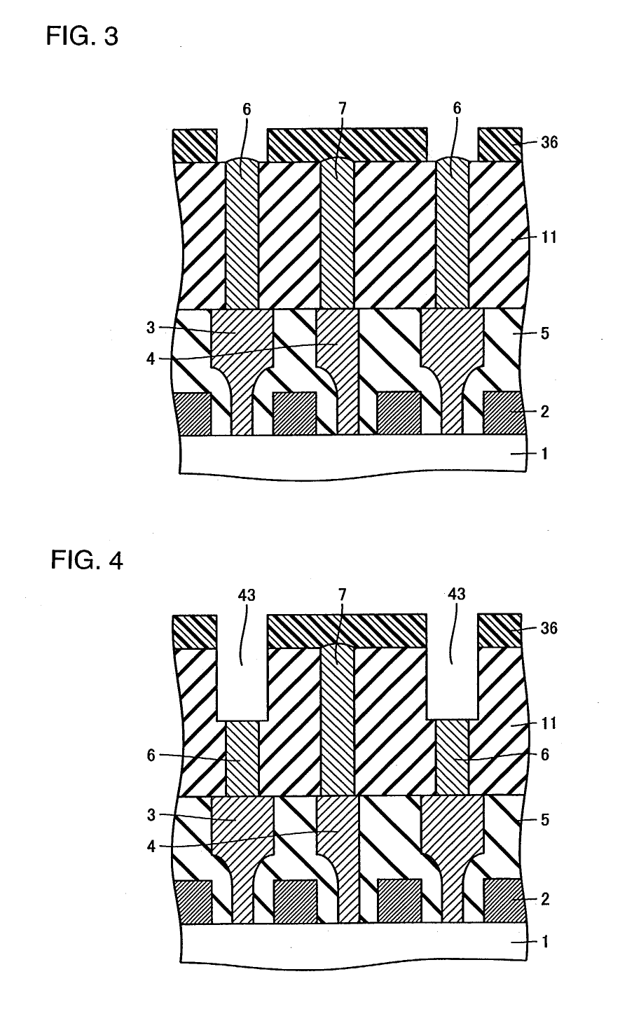

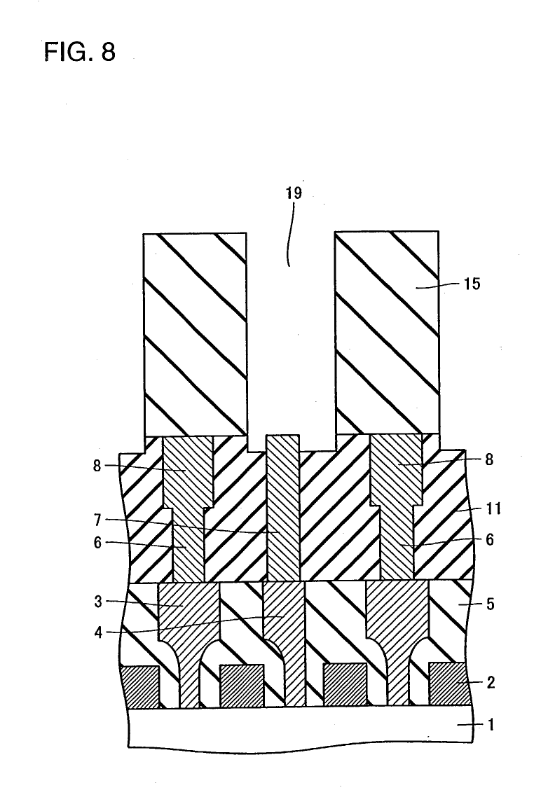

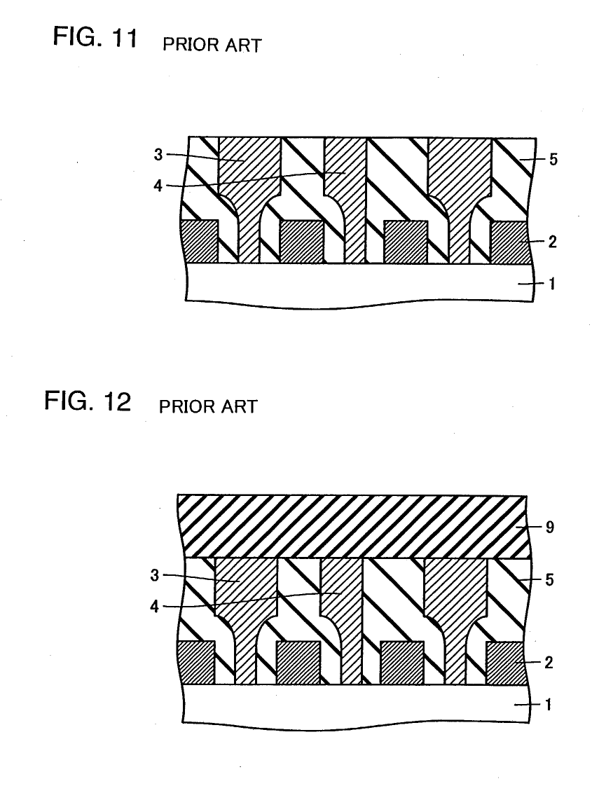

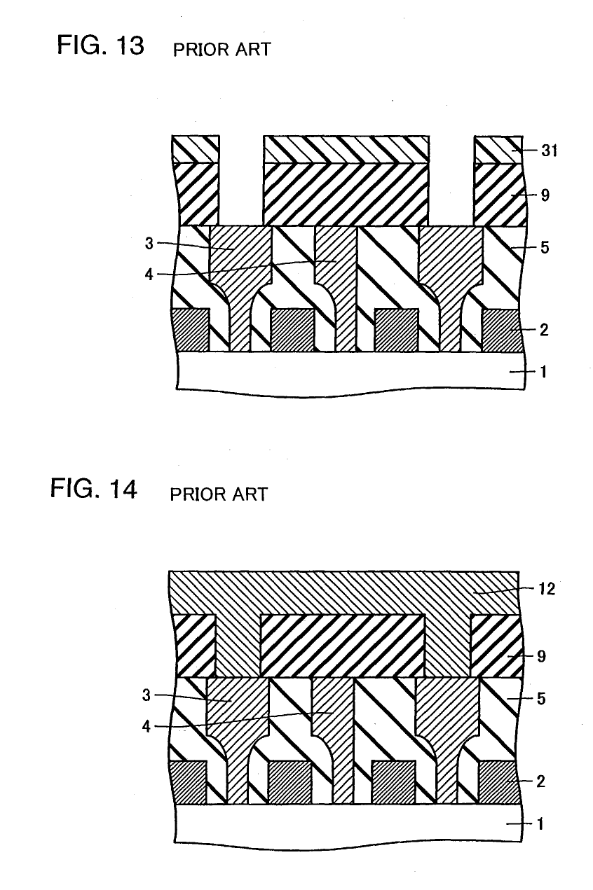

A method of fabricating a semiconductor device according to a first embodiment of the present invention is described with reference to FIGS. 11 and 1 to 9. First, a structure similar to that shown in FIG. 11 is fabricated by a well-known technique, similarly to the conventional method. As shown in FIG. 1, an interlayer dielectric film 11 is formed on the structure, and a resist film 35 is formed to cover the upper surface thereof. The resist film 35 is patterned to have openings in positions located immediately above bit line pads 3 and a storage node pad 4 respectively. This resist film 35 is employed as a mask for etching the interlayer dielectric film 11, thereby obtaining bit line contact holes 41 and a storage node contact hole 42 as shown in FIG. 2. In the state shown in FIG. 2, the resist film 35 is already removed. As shown in FIG. 3, the bit line contact holes 41 and the storage node contact hole 42 are filled up with conductors, thereby forming bit line contacts 6 and a storage node contact 7 respectively. A resist film 36 is formed on this structure and patterned along a pattern for arranging bit lines 8. Thus, not the upper surface of the storage node contact 7 but only the upper surfaces of the bit line contacts 6 are exposed due to the patterning along the pattern for arranging the bit lines 8.

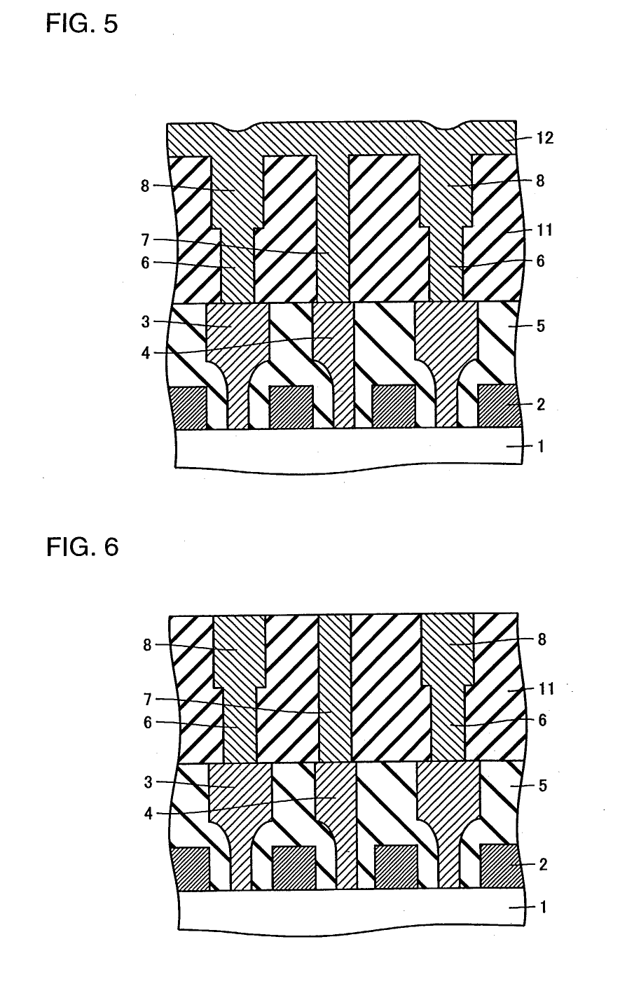

As shown in FIG. 4, bit line trenches 43 are formed by etching through the resist film 36 serving as a mask. As shown in FIG. 5, a conductor film 12 is formed to fill up the bit line trenches 43, thereby obtaining the bit lines 8. In this state, CMP (chemical mechanical polishing) is performed on the upper surface of the structure for exposing the interlayer dielectric film 11 as shown in FIG. 6. At this point, the upper surfaces of the bit lines 8 provided on the bit line contacts 6 and the upper surface of the storage node contact 7 are exposed on the uppermost surface of the structure.

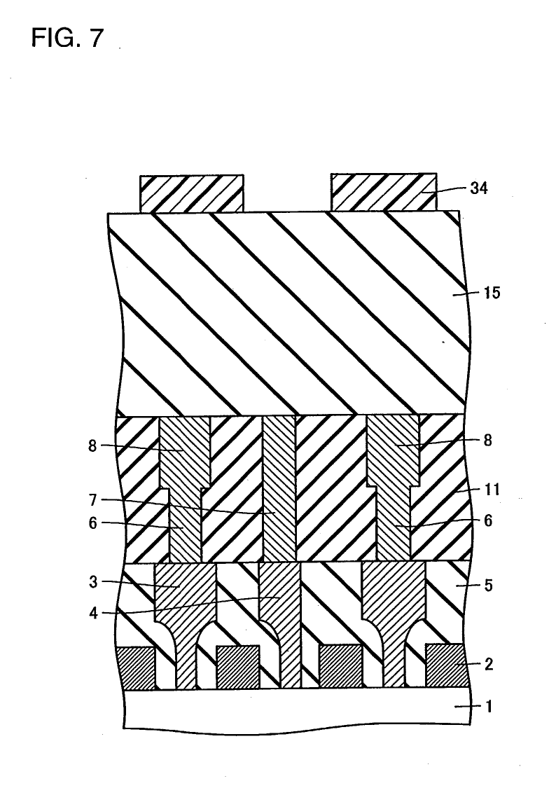

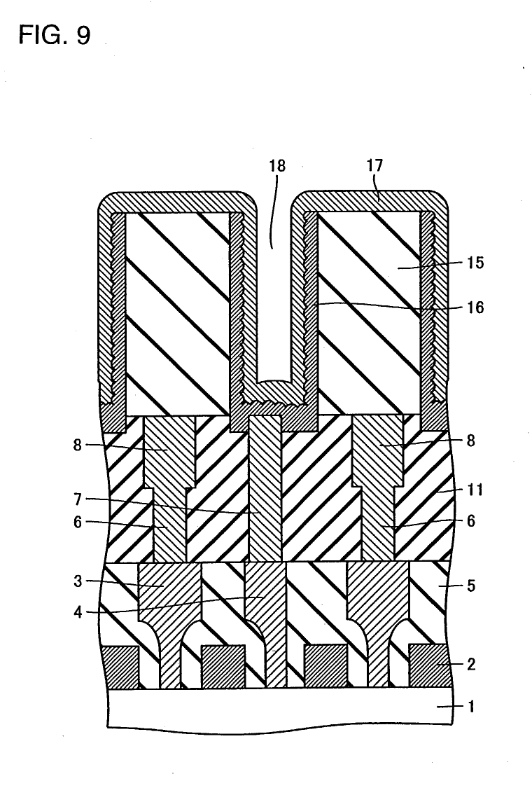

As shown in FIG. 7, an interlayer dielectric film 15 is formed on this structure, and a resist film 34 is formed to cover the upper surface thereof. The resist film 34 is patterned to have an opening in a portion to be formed with a storage node 18. Therefore, the opening of the resist film 34 is formed in a position located immediately above the storage node contact 7, as shown in FIG. 7. This resist film 34 is employed as a mask for etching the interlayer dielectric film 15 thereby obtaining a vertical opening 19 for the storage node 18. The upper end of the storage node contact 7 is exposed on the bottom of the vertical opening 19. As shown in FIG. 9, a storage node electrode 16 is formed in the shape of a cylinder covering the inner surface of the vertical opening 19, an insulator film (not shown) is formed to cover the storage node electrode 16, and a cell plate electrode 17 is formed to cover the surface of the insulator film formed in the vertical opening 19 and the upper surface of the interlayer dielectric film 15. Thus, a semiconductor device comprising the cylindrical storage node 18 is obtained.

In the aforementioned method, only three resist films 35, 36 and 34 may be employed for completing the storage node 18 as shown in FIG. 9 from the state exposing bit line pads 3 and a storage node pad 4 on the upper surface of an interlayer dielectric film 5 as shown in FIG. 11. In other words, the number of the resist films can be reduced by one as compared with the conventional method employing four resist films in total.

The storage node contact 7 may be formed to pass through only the interlayer dielectric film 11, and hence the total thickness of the interlayer dielectric film for receiving the storage node contact 7 can be reduced by about 30% as compared with the conventional method. Thus, the problem of enlargement of the frontage diameter resulting from etching can be relieved.

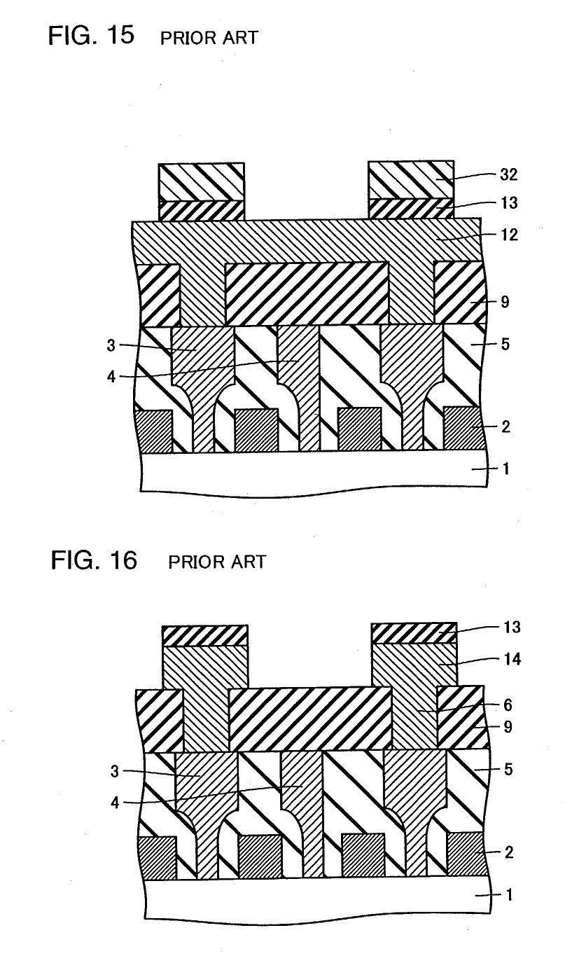

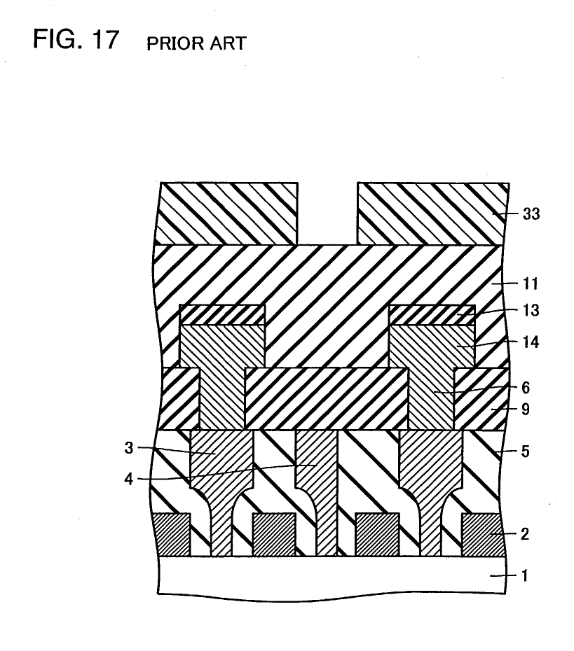

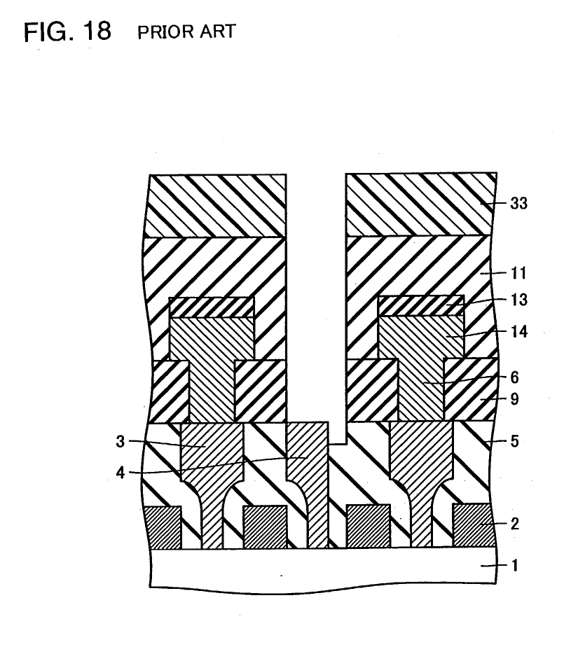

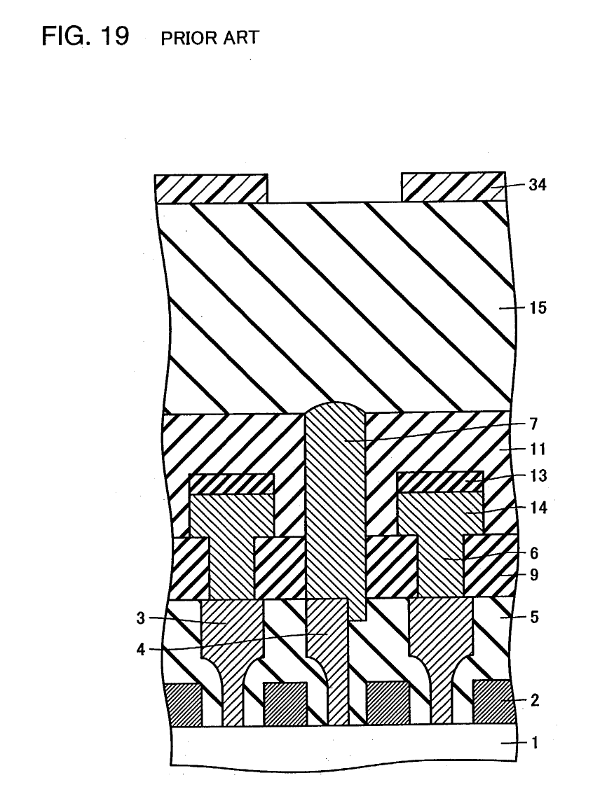

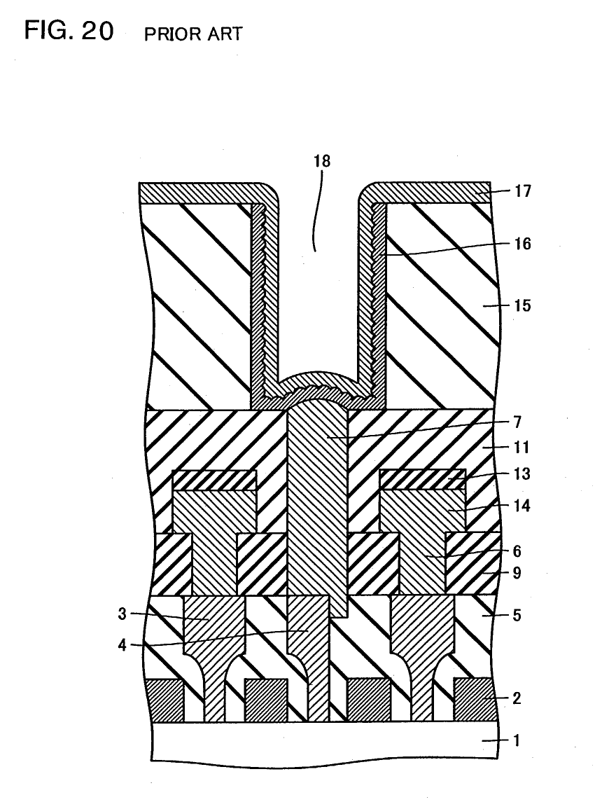

The bit lines 8 are not formed in the interlayer dielectric film 11 formed on the bit line contacts 6 dissimilarly to the conventional method (see FIGS. 15 and 16) but portions including the upper ends of the temporarily formed bit line contacts 6 (see FIG. 3) are enlarged by etching for forming the bit lines 8, whereby the aspect ratio of the length of the bit line contacts 6 located between the bit lines 8 and the bit line pads 3 can be reduced as compared with that in the conventional method. Thus, more correct working is enabled. While the thicknesses and the lengths are exaggeratedly illustrated in the drawings with rather inaccurate large-small relation and the aspect ratio does not necessarily reflect the actual size, the above is obvious in consideration of the fabrication method.

While CMP is employed for obtaining the structure shown in FIG. 6 from that shown in FIG. 5 in the aforementioned embodiment, conductor film dry etching may alternatively be employed in place of CMP. The bit line contacts 6, the storage node contact 7 and the bit lines 8 can be simultaneously formed also by conductor film dry etching.

(Second Embodiment)

A semiconductor device according to a second embodiment of the present invention is described with reference to FIG. 9. This semiconductor device, employed as a DRAM, is obtained by the method of fabricating a semiconductor device described with reference to the first embodiment. This semiconductor device comprises a storage node 18 and a first conductive layer. The first conductive layer includes bit line pads 3 and a storage node pad 4. An interlayer dielectric film 11 covers the upper side of the first conductive layer, and a plurality of contact holes are formed to vertically pass through the interlayer dielectric film 11. The plurality of contact holes reach the upper surface of the first conductive layer, and conductors are arranged in these contact holes thereby forming bit line contacts 6 and a storage node contact 7. The bit line contacts 6 communicate with the bit line pads 3 formed in the first conductive layer, and the storage node contact 7 communicates with the storage node pad 4 formed in the first conductive layer respectively. Bit lines 8 are arranged on the bit line contacts 6 as a second conductive layer. The bit lines 8 are larger in width than the bit line contacts 6. The upper surfaces of the bit lines 8 and that of the storage node contact 7 are substantially flush with each other.

The aforementioned structure can be obtained through the method of fabricating a semiconductor device described with reference to the first embodiment. In other words, the semiconductor device can be fabricated with a small number of resist films through a small number of steps. Thus, the semiconductor device can be more quickly fabricated at a lower cost as compared with the prior art.

(Third Embodiment)

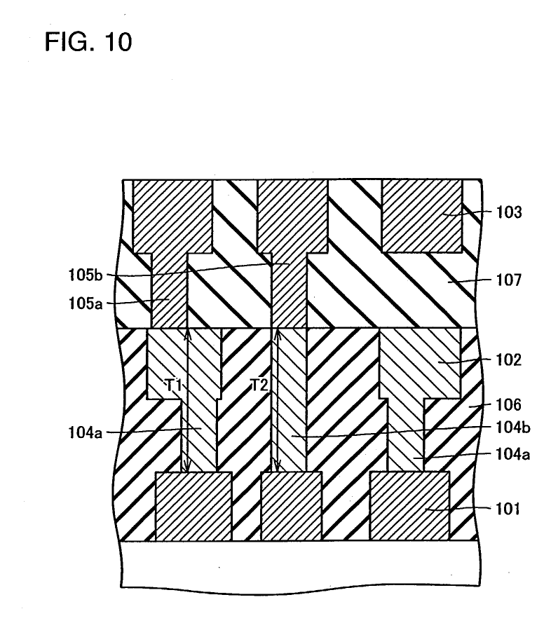

A third embodiment of the present invention is described with reference to an exemplary structure of another semiconductor device obtainable through the method of fabricating a semiconductor device described with reference to the first embodiment. The method of fabricating a semiconductor device described with reference to the first embodiment is also applicable to a structure shown in FIG. 10. In the semiconductor device shown in FIG. 10, first wires 101 are arranged on some layer, and second wires 102 are arranged above the first wires 101 through an interlayer dielectric film 106. First via holes 104a passing through the interlayer dielectric film 106 electrically connect parts of the first and second wires 101 and 102 with each other. Third wires 103 are arranged above the second wires 102 through an interlayer dielectric film 107. A second via hole 105a passing through the interlayer dielectric film 107 electrically connects part of the third wires 103 with part of the second wires 102. Another part of the third wires 103 is electrically connected with part of the first wires 102 through a second via hole 105b passing through the interlayer dielectric film 107 and a first via hole 104b passing through the interlayer dielectric film 106. The lower end of the second via hole 105b is directly connected with the upper end of the first via hole 104b without through a wiring layer. As viewed from the upper surfaces of the first wires 101, the height T1 of the upper surfaces of the second wires 102 and the height T2 of the upper surface of the first via hole 104b are substantially identical to each other.

Thus, the second wires 102 can be formed through the method of fabricating a semiconductor device described with reference to the first embodiment. According to the structure of this semiconductor device, vertically separated conductive layers such as the first wires 101 and the third wires 103 shown in FIG. 10 are electrically connected by directly coupling contacts with each other without providing other conductive layers therebetween, whereby the connection can be implemented with small spaces.

The structure of the semiconductor device shown in FIG. 10 can be applied to copper wires of a memory device, a logic device or a mixed device.

According to the inventive method of fabricating a semiconductor device, the number of resist films can be reduced as compared with the prior art. Further, the thickness of an interlayer dielectric film to be passed through in a single step is reduced as compared with that in the conventional method, whereby the problem of enlargement of the frontage diameter resulting from etching can be relieved. In addition, a semiconductor device can be fabricated through the aforementioned fabrication method by applying the inventive structure to the semiconductor device. In other words, the number of resist films can be reduced as compared with the prior art, whereby the semiconductor device can be fabricated through a small number of steps.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of fabricating a semiconductor device, comprising steps of:
forming an interlayer dielectric film to cover upper side of a first conductive layer;
simultaneously forming a plurality of contact holes reaching upper surface of said first conductive layer through said interlayer dielectric film;
expanding in width upper portion of part of said plurality of contact holes, thereby forming a trench for a second conductive layer; and
arranging conductors in said plurality of contact holes and said trench for a second conductive layer.

2. The method of fabricating a semiconductor device according to claim 1, wherein
said first conductive layer includes a bit line pad and a storage node pad,
said plurality of contact holes include a bit line contact hole reaching the upper surface of said bit line pad and a storage node contact hole reaching the upper surface of said storage node pad, and
said part of said plurality of contact holes is said bit line contact hole and said trench for a second conductive layer is a trench for forming a bit line.

3. A semiconductor device comprising:
an interlayer dielectric film covering upper side of a first conductive layer;
a plurality of contact holes reaching upper surface of said first conductive layer through said interlayer dielectric film and having conductors arranged therein; and
a second conductive layer, connected to the upper side of part of said plurality of contact holes, larger in width than said plurality of contact holes, wherein
the upper surface of said second conductive layer and the upper surfaces of those of said plurality of contact holes not formed with said second conductive layer are substantially flush with each other.

4. The semiconductor device according to claim 3, wherein
said first conductive layer includes a bit line pad and a storage node pad, and said plurality of contact holes include a bit line contact hole connected to the upper surface of said bit line pad and a storage node contact hole connected to the upper surface of said storage node pad, and
said bit line contact includes said second conductive layer among said plurality of contact holes, and said second conductive layer is a bit line.
